(19) United States
(12) Patent Application Publication
(10) Pub. No.: US 2026/0019047 A1
(43) Pub. Date: Jan. 15, 2026

(54) AMPLIFIER CIRCUIT AND AMPLIFICATION METHOD

(71) Applicant: Murata Manufacturing Co., Ltd., Nagaokakyo-shi (JP)

(72) Inventors: Kiichiro TAKENAKA, Nagaokakyo-shi (JP); Masatoshi HASE, Nagaokakyo-shi (JP)

(21) Appl. No.: 19/332,408

(22) Filed: Sep. 18, 2025

Related U.S. Application Data
(63) Continuation of application No. PCT/JP2024/004764, filed on Feb. 13, 2024.

(30) Foreign Application Priority Data
Mar. 31, 2023 (JP) 2023-057373

(51) Int. Cl. H03F 1/32; H03F 3/24

(52) U.S. Cl. CPC H03F 1/3288; H03F 3/245; H03F 2200/102; H03F 2200/105; H03F 2200/451

(57) ABSTRACT

An amplifier circuit is provided that includes a power amplifier circuit configured to amplify a radio frequency signal by using a power supply voltage V_{ET}, which can be a discrete voltage, and a variable phase-shift circuit connected to the power amplifier circuit. The variable phase-shift circuit is configured to change the phase-shift amount of a radio frequency signal based on the power supply voltage V_{ET}.

### CROSS REFERENCE TO RELATED APPLICATIONS

This application is a continuation of International Application No. PCT/JP2024/004764, filed Feb. 13, 2024, which claims priority to Japanese Patent Application No. Application No. 2023-057373, filed Mar. 31, 2023, the contents of each of which are hereby incorporated by reference in their entireties.

### TECHNICAL FIELD

The present disclosure relates to an amplifier circuit and an amplification method.

### BACKGROUND

Recently, tracking techniques have been applied to power amplifier circuits to improve power-added efficiency. U.S. Pat. No. 8,829,993 discloses a tracker circuit for digital envelope tracking (D-ET) that supplies a power supply voltage changing with time to multiple discrete levels. U.S. Pat. No. 10,686,407 discloses a tracker circuit for symbol power tracking (SPT) which supplies a voltage of multiple discrete levels.

In these existing techniques of the patent documents noted above, digital pre-distortion (DPD) may be used to reduce a nonlinear distortion occurring due to an operation of a power amplifier circuit in a nonlinear area. In DPD, an input signal to the power amplifier circuit is distorted in advance to cancel the nonlinear distortion occurring in the power amplifier circuit.

However, when a voltage of multiple discrete levels is supplied to a power amplifier circuit, a reduction, which is caused by DPD, of the nonlinear distortion may be limited.

### SUMMARY OF THE INVENTION

Accordingly, the exemplary aspects of the present disclosure provide an amplifier circuit and an amplification method that are configured to reduce the nonlinear distortion.

According to an exemplary aspect, an amplifier circuit is provided that includes a power amplifier circuit that is configured to amplify a radio frequency signal by using a voltage of a plurality of discrete levels, and a variable phase-shift circuit that is connected to the power amplifier circuit. The variable phase-shift circuit is configured to change a phase-shift amount of the radio frequency signal on the basis of the voltage of the discrete levels.

According to another exemplary aspect, an amplifier circuit is provided that includes a first input terminal configured to receive a voltage of a plurality of discrete voltage levels, a power amplifier circuit configured to amplify a radio frequency signal by using the voltage of the plurality of discrete voltage levels, a variable phase-shift circuit connected to the power amplifier circuit, and a control circuit configured to controls a phase-shift amount of the variable phase-shift circuit. An input end of the control circuit is connected to the first input terminal. An output end of the control circuit is connected to the variable phase-shift circuit.

In yet another exemplary aspect, an amplification method is provided that includes shifting a phase of a first radio frequency signal by a first phase-shift amount based on a first discrete voltage supplied to a power amplifier circuit; amplifying the first radio frequency signal by using the power amplifier circuit being supplied with the first discrete voltage, the first radio frequency signal having a phase having been shifted by the first phase-shift amount; shifting a phase of a second radio frequency signal by a second phase-shift amount on the basis of a second discrete voltage, the second phase-shift amount being different from the first phase-shift amount, the second discrete voltage being different from the first discrete voltage and supplied to the power amplifier circuit; and amplifying the second radio frequency signal by using the power amplifier circuit being supplied with the second discrete voltage, the second radio frequency signal having a phase having been shifted by the second phase-shift amount.

The exemplary aspects of the present disclosure provide for an amplifier circuit and an amplification method that reduces a nonlinear distortion in a tracking system.

### BRIEF DESCRIPTION OF DRAWINGS

FIG. 1A is a graph illustrating a transition example of power supply voltage in an APT mode.

FIG. 1B is a graph illustrating a transition example of power supply voltage in an analog ET mode.

FIG. 1C is a graph illustrating a transition example of power supply voltage in a digital ET mode.

FIG. 2 is a diagram illustrating the circuit configuration of a communication device according to an exemplary embodiment.

FIG. 3 is a diagram illustrating the circuit configuration of a power amplifier and its peripheral circuits according to an exemplary embodiment.

FIG. 4 is a graph illustrating a variable phase-shift circuit's characteristics between power supply voltage and phase-shift amount, according to an exemplary embodiment.

FIG. 5A is a graph illustrating the characteristics between output signal power and output signal phase of an amplifier circuit according to an exemplary embodiment.

FIG. 5B is a graph illustrating the characteristics between output signal power and output signal phase of an amplifier circuit according to a comparison example.

FIG. 6 is a flowchart of an amplification method according to an exemplary embodiment.

FIG. 7 is a plan view of an amplifier circuit according to an exemplary embodiment.

FIG. 8 is a diagram illustrating the circuit configuration of an amplifier circuit according to a first modified example of an exemplary embodiment.

FIG. 9A is a diagram illustrating the circuit configuration of an amplifier circuit according to a second modified example of an exemplary embodiment.

FIG. 9B is a diagram illustrating a phase modulation of a variable phase-shift circuit according to a second modified example of an exemplary embodiment.

FIG. 10 is a diagram illustrating the circuit configuration of a bias control circuit according to a second modified example of an exemplary embodiment.

FIG. 11 is a diagram illustrating the circuit configuration of an amplifier circuit according to a third modified example of an exemplary embodiment.

### DETAILED DESCRIPTION OF EMBODIMENTS

Exemplary embodiments of the present disclosure will be described below in detail by using the drawings. Each exemplary embodiment described below is a comprehensive or concrete example. The numeral values, the shapes, the materials, the components, the layout and the connection form of components, and the like described in the embodiments described below are exemplary, and are not intended to limit the present disclosure.

The figures are schematic views with appropriate emphasis, abbreviation, or adjustment of ratios for illustration of the exemplary aspects of the present disclosure, and are not necessarily illustrated strictly. The shapes, the positional relationship, and the ratios may be different from the actual ones. In the figures, substantially the same configurations are designated with the same reference numerals. It is noted that repeated description may be skipped or simplified.

In the figures described below, x axis and y axis are orthogonal to each other in a plane parallel to a principal surface of a substrate. Specifically, when a substrate is rectangular in plan view, x axis is parallel to a first side of the substrate; y axis is parallel to a second side orthogonal to the first side of the substrate. In addition, z axis is perpendicular to the principal surface of the substrate. The positive direction of z axis indicates the upward direction; its negative direction indicates the downward direction.

For purposes of this disclosure, in a component layout according to an exemplary aspect, the expression “plan view of a substrate” refs to a viewing of an object or component subjected to orthogonal projection to the xy plane from the z-axis positive side. The expression “in plan view, A overlaps B” can indicate that at least part of the area of A subjected to orthogonal projection to the xy plane overlaps at least part of the area of B subjected to orthogonal projection to the xy plane. The expression “A is disposed between B and C” indicates that at least one of line segments connecting any points in B to any points in C passes through A.

In a component layout in according to the exemplary aspects of the present disclosure, the expression “to dispose a component on/in a substrate” encompasses placement of the component on a principal surface of the substrate and placement of the component in the substrate. Moreover, the expression “to dispose a component on a principal surface of a substrate” encompasses, in addition to placement of the component which is in contact with the principal surface of the substrate, placement of the component above the principal surface without contact with the principal surface (for example, stacking the component on a different component which is disposed so as to be in contact with the principal surface). It is also noted that the expression “to dispose a component on a principal surface of a substrate” may encompass placement of the component in a recess formed on the principal surface. The expression “to dispose a component in a substrate” encompasses, in addition to the component encapsulated in the substrate, the component, all of which is disposed between the principal surfaces of the substrate but a part of which is not covered by the substrate, and the component, only a part of which is disposed in the substrate.

In a circuit configuration in the present disclosure, the phrase “to be connected” encompasses, not only the case of direct connection using a connection terminal and/or a wiring conductor, but also the case of electrical connection via other circuit devices. Moreover, the phrase “to be connected between A and B” can refer to a connection, between A and B, to both A and B.

In the present disclosure, the expression “to dispose component (device) A in series to path B” can indicate a connection of both the signal input end and the signal output end of component (device) A to wiring lines, electrodes, or terminals included in path B.

In the exemplary aspects of the present disclosure, the term “terminal” refers to a point where a conductor in a component terminates. When the impedance of a conductor between components is sufficiently low, the terminal is interpreted, not only as a single point, but also as any point on the conductor between the components or as the entire conductor.

Terms which indicate relationship between components, such as “parallel” and “perpendicular”, terms which indicate the shapes of components, such as “rectangular”, and numerical ranges do not represent only strict meaning, and mean substantially equivalent ranges, for example, having errors in the order of a few percent.

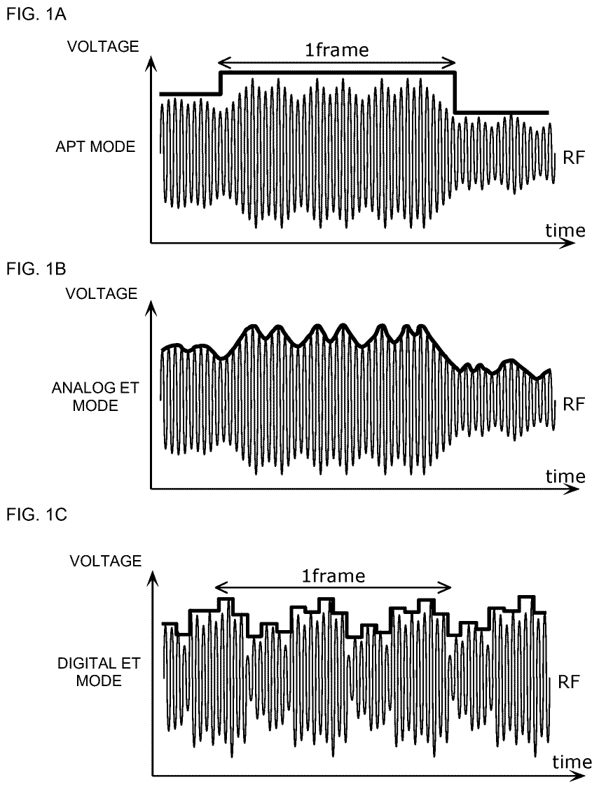

First, tracking mode for supplying a power amplifier with a power supply voltage adjusted dynamically with time on the basis of a radio frequency signal will be described as a technique of amplifying a radio frequency signal with high efficiency. The tracking mode is a mode for dynamically adjusting a power supply voltage that is to be applied to a power amplifier. The tracking mode has some types. Here, an average power tracking (APT) mode and envelope tracking (ET) modes (including an analog ET mode and a digital ET mode) will be described by referring to FIGS. 1A to 1C. In FIGS. 1A to 1C, the horizontal axis represents time; the vertical axis represents voltage. A thick solid line represents power supply voltage; a thin solid line (waveform) represents modulated waves.

FIG. 1A is a graph illustrating a transition example of power supply voltage in the APT mode. In the APT mode, the power supply voltage is changed among multiple discrete voltage levels in each frame on the basis of the average power. As a result, the power supply voltage signal forms rectangular waves.

According to an exemplary aspect, a frame refers to a unit with which a radio frequency signal (e.g., modulated waves) is formed. For example, in 5GNR (5th Generation New Radio) and LTE (Long Term Evolution), a frame contains ten subframes; each subframe contains multiple slots; each slot is formed by multiple symbols. The subframe length is 1 ms and the frame length is 10 ms according to the exemplary aspect.

Moreover, in an exemplary aspect, a mode in which the voltage level is changed in units of one frame or larger units on the basis of the average power is called the APT mode, and is differentiated from a mode in which the voltage level is changed in units smaller than a frame (for example, a subframe, a slot, or a symbol). For example, the mode in which the voltage level is changed in units of a symbol is called a symbol power tracking (SPT) mode, and is differentiated from the APT mode.

FIG. 1B is a graph illustrating a transition example of power supply voltage in the analog ET mode. In the analog ET mode, the power supply voltage is changed continuously on the basis of the envelope signal, thus following the envelope of modulated waves.

The envelope signal is a signal indicating the envelope of modulated waves. The envelope value is expressed, for example, by the square root of (I²+Q²). (I, Q) represents a constellation point. A constellation point is a point indicating a modulated signal, which is obtained through digital modulation, on a constellation diagram. (I, Q) is defined, for example, by a BBIC (Baseband Integrated Circuit), for example, on the basis of information about transmission.

FIG. 1C is a graph illustrating a transition example of power supply voltage in the digital ET mode. In the digital ET mode, the power supply voltage is changed among multiple discrete voltage levels within one frame on the basis of an envelope signal, thus following the envelope of a modulated signal. As a result, the power supply voltage signal forms rectangular waves.

### EXEMPLARY EMBODIMENT

### 1 Circuit Configuration of Communication Device 7

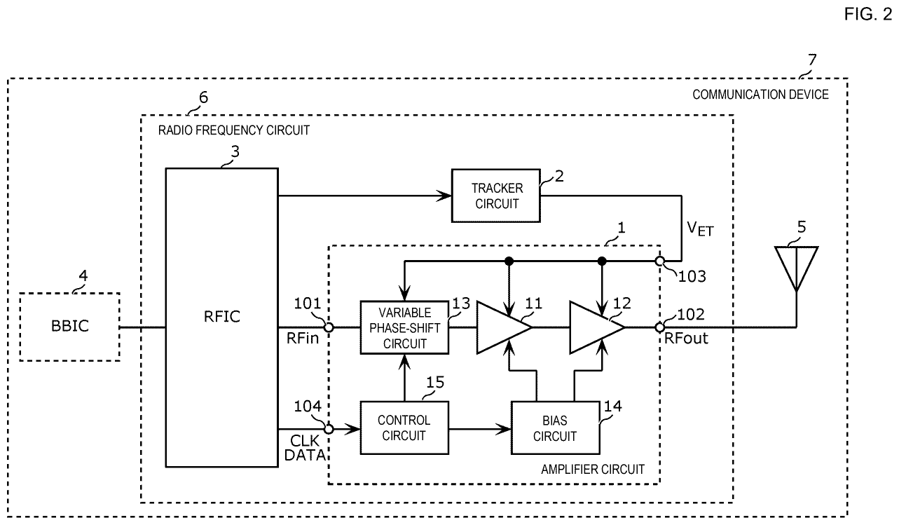

The circuit configuration of a communication device 7 according to the present embodiment will be described by referring to FIG. 2. FIG. 2 is a diagram illustrating the circuit configuration of the communication device 7 according to the embodiment.

FIG. 2 illustrates an exemplified circuit configuration. According to an exemplary aspect, the communication device 7 may be implemented by using any of diverse circuit implementations and circuit techniques. Thus, the description below about the communication device 7 is not to be interpreted limitedly.

The communication device 7 corresponds to a user equipment (UE) in a cellular network, and typically is a mobile phone, a smartphone, a tablet computer, a wearable device, or the like. According to an exemplary aspect, the communication device 7 may be an IoT (Internet of Things) sensor device, a medical/healthcare device, a vehicle, an unmanned aerial vehicle (UAV) (so-called drone), or an automated guided vehicle (AGV). The communication device 7 may be implemented as a BS (Base Station) in a cellular network or an access point in a wireless local area network (WLAN).

As illustrated in FIG. 2, the communication device 7 includes a radio frequency circuit 6, a BBIC (Baseband Integrated Circuit) 4, and an antenna 5.

The BBIC 4 is a baseband signal processing circuit which performs signal processing using an intermediate frequency band of lower frequency than that of the radio frequency signal transmitted by the radio frequency circuit 6. For example, the BBIC 4 subjects' digital modulation to a bit sequence indicating an image signal for image display and/or an audio signal for conversation through a speaker, for generation of a digital IQ signal. The generated digital IQ signal is supplied to an RFIC 3. The BBIC 4 is not necessarily included in the communication device 7.

The antenna 5, which is connected to the radio frequency circuit 6, transmits a radio frequency signal which is output from the radio frequency circuit 6. The antenna 5 is not necessarily included in the communication device 7. The communication device 7 may further include, in addition to the antenna 5, one or more antennas.

The radio frequency circuit 6, which is connected between the BBIC 4 and the antenna 5, upconverts a baseband signal, which has been generated by the BBIC 4, to generate a radio frequency signal for output to the antenna 5. The radio frequency circuit 6 includes an amplifier circuit 1, a tracker circuit 2, and the RFIC (Radio Frequency Integrated Circuit) 3.

According to an exemplary aspect, the tracker circuit 2 is configured to supply a voltage of multiple discrete voltage levels, as a power supply voltage (V_{ET}), to the amplifier circuit 1 on the basis of a tracking mode applied to the amplifier circuit 1. In the present embodiment, the D-ET mode, the SPT mode, and even the APT mode may be used as the tracking mode. However, available tracking modes are not limited to these configurations as would be appreciated to one skilled in the art.

According to an exemplary aspect, the tracker circuit 2 may be an existing tracker circuit 2 that is configured to operate in the D-ET mode, the SPT mode, or the APT mode. For example, the tracker circuit 2 may be the tracker circuit described above in U.S. Pat. Nos. 8,829,993 and 10,686,407. Thus, it should be appreciated that the tracker circuit 2 is not limited to these configurations.

The RFIC 3 is an example of a signal processing circuit which processes a radio frequency signal. The RFIC 3 may include a DPD circuit, and may distort in advance a digital IQ signal, which is supplied from the BBIC 4, on the basis of a DPD mathematical model. The mathematical model may be, for example, a memoryless polynomial model, a memory polynomial model (MPM), or a generalized memory polynomial model (GMP), but is not limited to these configurations according to various exemplary aspects.

According to an exemplary aspect, the RFIC 3 is configured to convert a digital IQ signal, which has been distorted in advance, to an analog IQ signal, which has been distorted in advance. The RFIC 3 is configured to perform quadrature modulation and upconverting on the analog IQ signal to generate a radio frequency signal. The generated radio frequency signal is supplied to a radio-frequency input terminal 101 of the amplifier circuit 1.

According to an exemplary aspect, the RFIC 3 further includes a control unit which controls a bias circuit 14 or the like included in the amplifier circuit 1. The control unit of the RFIC 3 is configured to supply a digital control signal to a control input terminal 104 of the amplifier circuit 1. It should be appreciated that some or all of the functions as the control unit of the RFIC 3 may be implemented in the outside of the RFIC 3, and may be implemented, for example, in the BBIC 4, the amplifier circuit 1, or the tracker circuit 2.

The amplifier circuit 1 includes power amplifiers 11 and 12, a variable phase-shift circuit 13, the bias circuit 14, a control circuit 15, the radio-frequency input terminal 101, a radio-frequency output terminal 102, a power-supply-voltage input terminal 103, and the control input terminal 104.

According to an exemplary aspect, the power amplifier 11, which is an exemplary first amplifier, is configured to amplify a radio frequency signal, which is output from the variable phase-shift circuit 13, by using the voltage V_{ET} Of multiple discrete levels, which is received from the tracker circuit 2.

According to an exemplary aspect, the power amplifier 12, which is an exemplary second amplifier, is configured to amplify a radio frequency signal, which is output from the power amplifier 11, by using the voltage V_{ET} of multiple discrete levels, which is received from the tracker circuit 2.

The power amplifier 11 is disposed on the driver stage (preceding stage); the power amplifier 12 is disposed on the power stage (subsequent stage) and is connected to the output end of the power amplifier 11.

The power amplifiers 11 and 12 form a multistage power amplifier circuit.

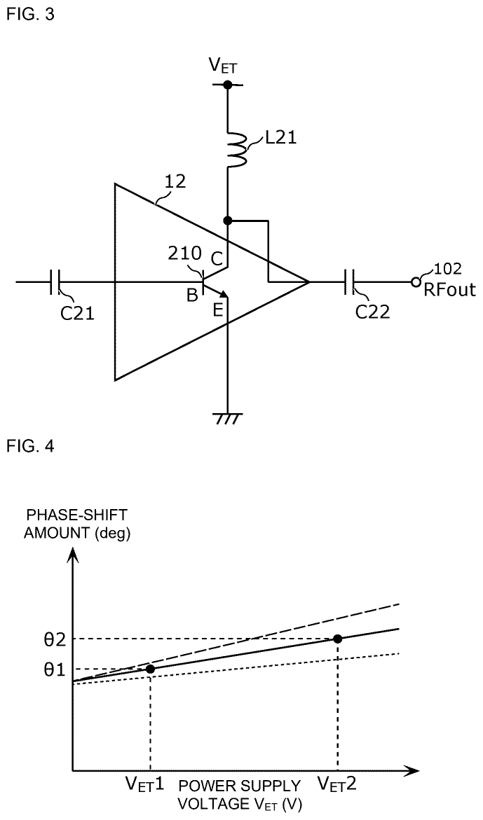

FIG. 3 is a diagram illustrating the circuit configuration of the power amplifier 12 and its peripheral circuits, according to the embodiment. As illustrated in FIG. 3, the power amplifier 12 includes an amplifier transistor 210. The amplifier circuit 1 includes an inductor L21 and capacitors C21 and C22 which are not illustrated in FIG. 2.

The amplifier transistor 210 is an amplifier device which has, for example, a collector, an emitter, and a base; which is an emitter-grounded bipolar transistor; and which amplifies a radio-frequency current, which is input to the base, for output from the collector. The amplifier transistor 210 may be a field-effect transistor having a drain (corresponding to a collector), a source (corresponding to an emitter), and a gate (corresponding to a base).

The base of the amplifier transistor 210 is connected to the output end of the power amplifier 11 through the capacitor C21. The collector of the amplifier transistor 210 is connected to the power-supply-voltage input terminal 103 through the inductor L21 and is connected to the radio-frequency output terminal 102 through the capacitor C22. The emitter of the amplifier transistor 210 is grounded.

The capacitors C21 and C22 are DC cutting capacitive devices. In particular, the capacitor C21 may be configured to prevent leakage of a direct current to the power amplifier 11 side. The leakage is caused by a direct-current bias voltage which is applied to the base of the amplifier transistor 210 from the bias circuit 14. Moreover, the capacitor C22 may be configured to remove direct-current components of a radio-frequency amplified signal on which a direct-current bias voltage has been superimposed.

The inductor L21, which is a choke coil, can be configured to suppress leakage of an amplified radio frequency signal, which has been amplified by the amplifier transistor 210, to the power-supply-voltage input terminal 103.

The power amplifier 12 may have a bypass capacitor connected between the ground and the path connecting the inductor L21 to the collector. The power amplifier 12 may have an inductor connected between the emitter and the ground.

According to the configuration of the power amplifier 12 and its peripheral circuits, in the state in which the power supply voltage V_{ET} is supplied from the tracker circuit 2 to the collector of the amplifier transistor 210, a radio frequency signal, which is input to the power amplifier 12, serves as a base current Ib, which flows from the base of the amplifier transistor 210 to the emitter. The amplifier transistor 210 amplifies the base current Ib, which serves as a collector current Icc, and a radio frequency signal RFout in accordance with the collector current Icc is output from the radio-frequency output terminal 102.

The power amplifier 11 has a circuit configuration substantially the same as the above-described configuration of the power amplifier 12. The base of the amplifier transistor included in the power amplifier 11 is connected to the variable phase-shift circuit 13; the emitter is grounded; the collector is connected to the power-supply-voltage input terminal 103 through an inductor, and is connected to the base of the amplifier transistor 210 of the power amplifier 12 through a capacitor.

According to the configuration, the power amplifier circuits included in the power amplifiers 11 and 12 amplify a radio frequency signal by using the discrete voltage V_{ET}.

According to an exemplary aspect, impedance matching devices may be connected between the variable phase-shift circuit 13 and the power amplifier 11 and between the power amplifier 11 and the power amplifier 12.

Referring back to FIG. 2 again, the circuit configuration of the amplifier circuit 1 will be described.

The variable phase-shift circuit 13, which is connected to the power amplifier 11, is configured to change the phase-shift amount of a radio frequency signal, which is input to the power amplifier 11, on the basis of the discrete voltage V_{ET}. Specifically, the variable phase-shift circuit 13 receives the discrete voltage V_{ET} through the power-supply-voltage input terminal 103 and changes the phase-shift amount of a radio frequency signal, which is to be input to the power amplifier 11, on the basis of the discrete voltage V_{ET}.

The bias circuit 14 is configured to supply bias voltages (bias currents) to the power amplifiers 11 and 12.

The control circuit 15 controls the variable phase-shift circuit 13 and the bias circuit 14. Specifically, the control circuit 15 controls the phase-shift amount of the variable phase-shift circuit 13 and the bias voltages of the bias circuit 14 on the basis of the digital control signal received from the RFIC 3 through the control input terminal 104.

According to an exemplary aspect, the bias circuit 14 may be included in the control circuit 15.

### 2 Phase-Shift Amount Characteristics of Variable Phase-Shift Circuit 13 and AM-PM Characteristics of Amplifier Circuit 1

FIG. 4 is a graph illustrating characteristics between power supply voltage and phase-shift amount of the variable phase-shift circuit 13 according to the embodiment. As illustrated in FIG. 4, when a power supply voltage V_{ET}1 (first discrete voltage) is supplied to the power amplifiers 11 and 12, the variable phase-shift circuit 13 shifts the phase of a radio frequency signal, which is received through the radio-frequency input terminal 101, by a phase-shift amount θ1 (first phase-shift amount). When a power supply voltage V_{ET}2 (second discrete voltage) is supplied to the power amplifiers 11 and 12, the variable phase-shift circuit 13 shifts the phase of a radio frequency signal, which is received through the radio-frequency input terminal 101, by a phase-shift amount θ2 (second phase-shift amount). The power supply voltage V_{ET}2 is larger than the power supply voltage V_{ET}1; the phase-shift amount θ2 is larger than the phase-shift amount θ1.

As described above, the variable phase-shift circuit 13 changes the phase-shift amount of a radio frequency signal in accordance with the discrete power supply voltage V_{ET} which is supplied to the amplifier circuit 1, achieving a reduction of the nonlinear distortion of the radio frequency signal which has been amplified by the amplifier circuit 1.

The variable phase-shift circuit 13 may change the inclination of the characteristics between power supply voltage V_{ET} and phase-shift amount, which is illustrated in FIG. 4, in units of one or more frames. Specifically, the control circuit 15 supplies the variable phase-shift circuit 13 with a control signal for changing the inclination of the characteristics between power supply voltage V_{ET} and phase-shift amount on the basis of the digital control signal received from the control input terminal 104. On the basis of the control signal supplied from the control circuit 15, the variable phase-shift circuit 13 changes the characteristics between power supply voltage V_{ET} and phase-shift amount, in units of one or more frames, for example, from the characteristics indicated by the solid line in FIG. 4 to the characteristics indicated by a dashed line.

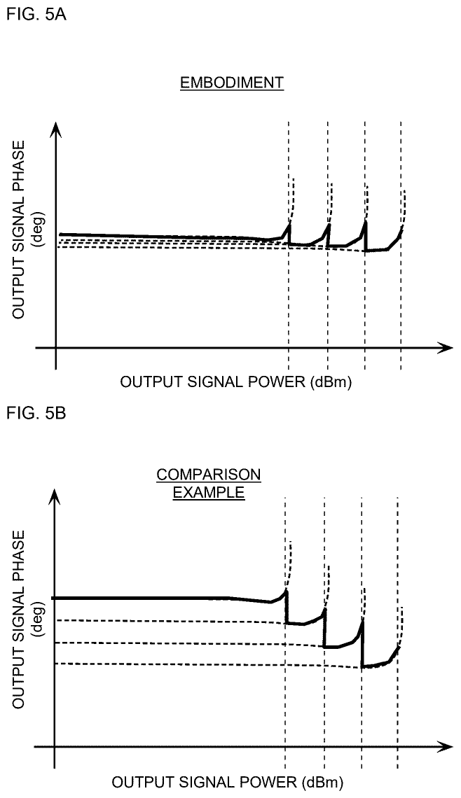

FIG. 5A is a graph illustrating characteristics between output signal power (AM) and output signal phase (PM) of the amplifier circuit 1 according to the embodiment. FIG. 5B is a graph illustrating characteristics between output signal power (AM) and output signal phase (PM) of an amplifier circuit according to a comparison example.

The amplifier circuit according to the comparison example is different from the amplifier circuit 1 according to the embodiment only in the configuration in which the variable phase-shift circuit 13 is not disposed.

As illustrated in FIG. 5B, the amplifier circuit according to the comparison example, in which a voltage of multiple discrete levels is supplied to the power amplifier circuit, has characteristics between output signal power (AM) and output signal phase (PM) with discontinuous and steep changes in a nonlinear area (large-signal area).

In contrast, the amplifier circuit 1 according to the present embodiment, in which a voltage of multiple discrete levels is supplied to the power amplifier circuit, has characteristics between output signal power (AM) and output signal phase (PM) with remaining slight discontinuity in the nonlinear area (large-signal area), but with suppression of steep changes. That is, in the amplifier circuit 1 according to the present embodiment, the variable phase-shift circuit 13 changes the phase-shift amount of a radio frequency signal in accordance with the power supply voltage V_{ET} (discrete voltage), achieving improvement of the characteristics between output signal power (AM) and output signal phase (PM) and a reduction of the nonlinear distortion in the tracking system.

In the amplifying system using a tracking system, a DPD circuit is disposed in the RFIC 3. The DPD circuit is configured to distort in advance a radio frequency signal, which is to be input to the power amplifier circuit, for a reduction of the nonlinear distortion of the radio frequency signal having been amplified by the power amplifier circuit. In the amplifier circuit according to the comparison example, the characteristics between output signal power (AM) and output signal phase (PM) has discontinuous and steep changes in the nonlinear area (large-signal area). This causes a larger load of the DPD circuit for reduction of the changes, resulting in degradation of the characteristics and an increase of power consumption.

In contrast, in the amplifier circuit 1 according to the present embodiment, the changes of the characteristics between output signal power (AM) and output signal phase (PM) in the nonlinear area (large-signal area) are suppressed, achieving a smaller load of the DPD circuit and suppression of the nonlinear distortion with high accuracy.

As illustrated in FIG. 4, the variable phase-shift circuit 13 may be configured to increase the phase-shift amount as the power supply voltage V_{ET} (discrete voltage) increases.

According to this configuration, the variable phase-shift circuit 13 changes the phase-shift amount of a radio frequency signal in accordance with the power supply voltage V_{ET} (discrete voltage), achieving improvement of the characteristics between output signal power (AM) and output signal phase (PM). This achieves a reduction of the nonlinear distortion in the tracking system.

### 3 Amplification Method of Amplifier Circuit 1

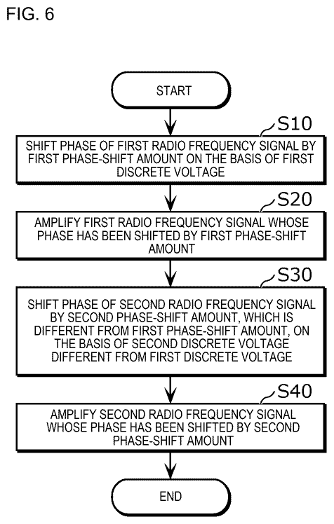

A method of amplifying a radio frequency signal, which is performed by the amplifier circuit 1 configured as described above, will be described by referring to FIG. 6. FIG. 6 is a flowchart of the amplification method according to the embodiment.

The variable phase-shift circuit 13 shifts the phase of a first radio frequency signal by the first phase-shift amount on the basis of the power supply voltage V_{ET}1 (first discrete voltage) supplied to the power amplifiers 11 and 12 (S10).

The amplifier circuit 1 causes the power amplifiers 11 and 12, to which the power supply voltage V_{ET}1 (first discrete voltage) is being supplied, to amplify the first radio frequency signal whose phase has been shifted by the first phase-shift amount (S20).

The variable phase-shift circuit 13 shifts the phase of a second radio frequency signal by the second phase-shift amount, which is different from the first phase-shift amount, on the basis of the power supply voltage V_{ET}2 (second discrete voltage), which is different from the power supply voltage V_{ET}1 (first discrete voltage) and which is supplied to the power amplifiers 11 and 12 (S30).

The amplifier circuit 1 causes the power amplifiers 11 and 12, to which the power supply voltage V_{ET}2 (second discrete voltage) is being supplied, to amplify the second radio frequency signal whose phase has been shifted by the second phase-shift amount (S40).

According to this configuration, in the amplifier circuit 1, the variable phase-shift circuit 13 changes the phase-shift amount of a radio frequency signal in accordance with the power supply voltage V_{ET} (discrete voltage), achieving improvement of the characteristics between output signal power (AM) and output signal phase (PM). This achieves a reduction of the nonlinear distortion in the tracking system.

### 4 Implementation Configuration of Amplifier Circuit 1

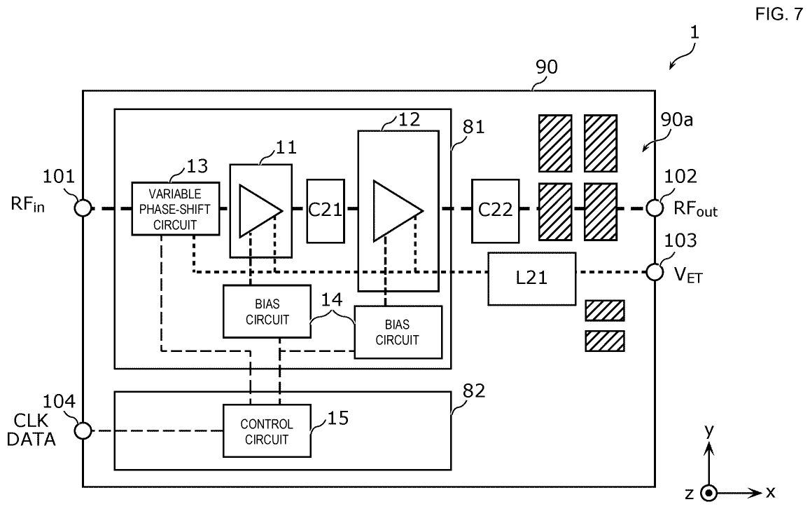

FIG. 7 is a plan view of the amplifier circuit 1 according to the embodiment. FIG. 7 does not illustrate some of wiring lines connecting multiple circuit components disposed on a module substrate 90. FIG. 7 does not illustrate a resin member and a shield electrode layer disposed on a principal surface of the module substrate 90. The resin member and the shield electrode layer may be excluded according to an exemplary aspect.

As illustrated in FIG. 7, the amplifier circuit 1 includes the module substrate 90, the power amplifiers 11 and 12, the variable phase-shift circuit 13, the bias circuits 14, the control circuit 15, the capacitors C21 and C22, the inductor L21, the radio-frequency input terminal 101, the radio-frequency output terminal 102, the power-supply-voltage input terminal 103, and the control input terminal 104.

The power amplifiers 11 and 12, the variable phase-shift circuit 13, the bias circuits 14, the control circuit 15, the capacitors C21 and C22, and the inductor L21 are disposed on a principal surface 90a of the module substrate 90. In FIG. 7, the module substrate 90 is rectangular in plan view, but the shape of the module substrate 90 is not limited to this configuration. Some of the power amplifiers 11 and 12, the variable phase-shift circuit 13, the bias circuits 14, the control circuit 15, the capacitors C21 and C22, and the inductor L21 may be disposed on a principal surface opposite the principal surface 90a or in the module substrate 90 according to alternative exemplary aspects.

According to an exemplary aspect, the module substrate 90 may be, for example, a low temperature co-fired ceramics (LTCC) substrate or a high temperature co-fired ceramics (HTCC) substrate, a component-embedded board, a substrate having a redistribution layer (RDL), or a printed circuit board which has a multilayer structure of multiple dielectric layers, but is not limited to these configurations.

The power amplifiers 11 and 12, the variable phase-shift circuit 13, the bias circuits 14, and the capacitor C21 are included in an integrated circuit 81. The control circuit 15 is included in an integrated circuit 82.

The integrated circuits 81 and 82 are formed, for example, by using CMOS (Complementary Metal Oxide Semiconductor). Specifically, the integrated circuits 81 and 82 may be manufactured through a SOI (Silicon on Insulator) process in an exemplary aspect. The integrated circuit 81 is not limited to a CMOS as would be appreciated to one skilled in the art.

According to this configuration, the amplifier circuit 1 achieves a reduction in size.

### 5 Circuit Configuration of Amplifier Circuit 1A According to First Modified Example

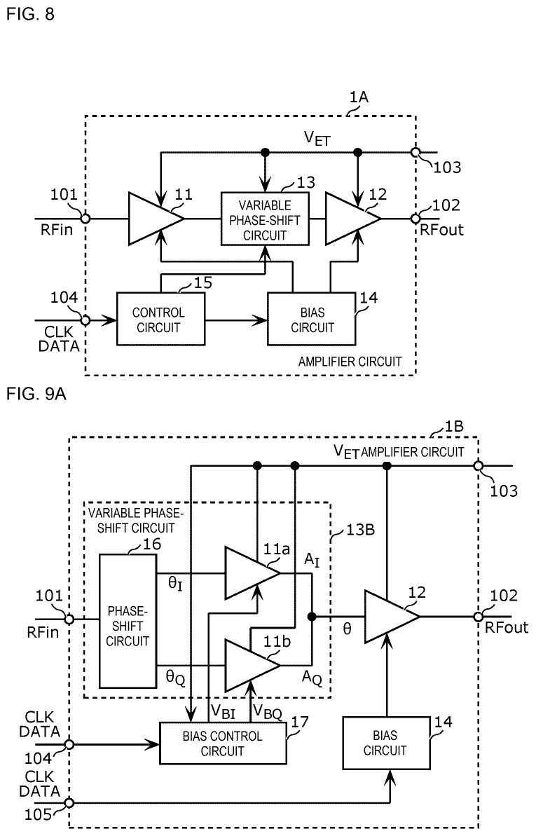

FIG. 8 is a diagram illustrating the circuit configuration of an amplifier circuit 1A according to a first modified example of the embodiment. As illustrated in FIG. 8, the amplifier circuit 1A includes the power amplifiers 11 and 12, the variable phase-shift circuit 13, the bias circuit 14, the control circuit 15, the radio-frequency input terminal 101, the radio-frequency output terminal 102, the power-supply-voltage input terminal 103, and the control input terminal 104. The amplifier circuit 1A according to the present modified example is different from the amplifier circuit 1 according to the embodiment in the connection configuration of the variable phase-shift circuit 13 and the power amplifiers 11 and 12. The same configurations of the amplifier circuit 1A according to the present modified example as those of the amplifier circuit 1 according to the embodiment will not be described, and different configurations will be mainly described.

According to an exemplary aspect, the power amplifier 11, which is an exemplary first amplifier, is configured to amplify a radio frequency signal, which is received through the radio-frequency input terminal 101, by using the voltage V_{ET} of multiple discrete levels which is received from the tracker circuit 2.

According to an exemplary aspect, the power amplifier 12, which is an exemplary second amplifier, is configured to amplify a radio frequency signal, which is output from the variable phase-shift circuit 13, by using the voltages V_{Et} of multiple discrete levels which is received from the tracker circuit 2.

The power amplifier 11 is disposed on the driver stage (preceding stage); the power amplifier 12 is disposed on the power stage (subsequent stage) and is connected to the output end of the power amplifier 11 through the variable phase-shift circuit 13.

The power amplifiers 11 and 12 form a multistage power amplifier circuit.

The variable phase-shift circuit 13, which is connected to the output end of the power amplifier 11 and the input end of the power amplifier 12, is configured to change the phase-shift amount of a radio frequency signal, which is to be input to the power amplifier 12, on the basis of the discrete voltage V_{ET}. Specifically, the variable phase-shift circuit 13 receives the discrete voltage V_{ET} through the power-supply-voltage input terminal 103 and changes the phase-shift amount of a radio frequency signal, which is to be input to the power amplifier 12, on the basis of the discrete voltage V_{ET}.

According to this configuration, the variable phase-shift circuit 13 changes the phase-shift amount of a radio frequency signal, which is to be input to the power amplifier 12, in accordance with the power supply voltage V_{ET} (discrete voltage), achieving improvement of the characteristics between output signal power (AM) and output signal phase (PM). This achieves a reduction of the nonlinear distortion in the tracking system.

### 6 Circuit Configuration of Amplifier Circuit 1B According to Second Modified Example

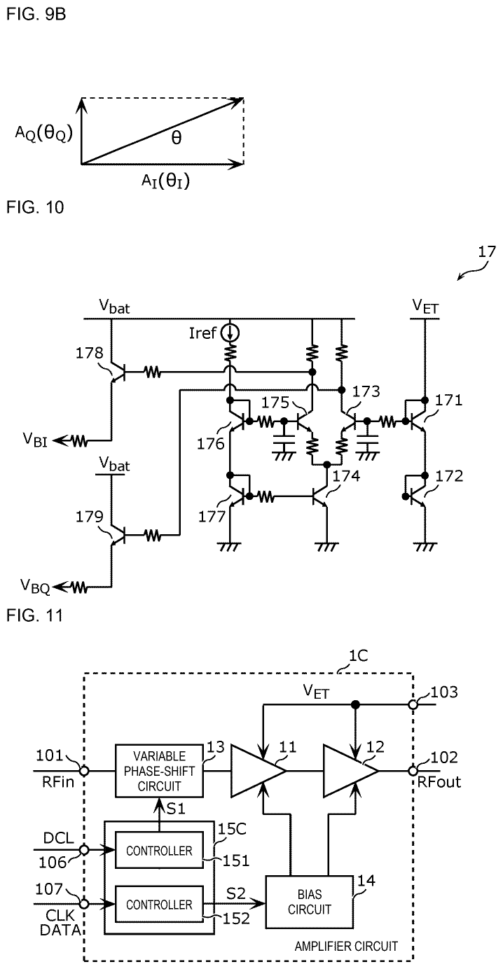

FIG. 9A is a diagram illustrating the circuit configuration of an amplifier circuit 1B according to a second modified example of the embodiment. As illustrated in FIG. 9A, the amplifier circuit 1B includes the power amplifier 12, a variable phase-shift circuit 13B, the bias circuit 14, a bias control circuit 17, the radio-frequency input terminal 101, the radio-frequency output terminal 102, the power-supply-voltage input terminal 103, and control input terminals 104 and 105.

According to an exemplary aspect, the power amplifier 12, which is included in the power amplifier circuit, is configured to amplify a radio frequency signal, which is output from the variable phase-shift circuit 13B, by using the voltage of multiple discrete levels (power supply voltage V_{ET}) received from the tracker circuit 2.

The power-supply-voltage input terminal 103, which is an exemplary first input terminal, receives the power supply voltage V_{ET} which is output from the tracker circuit 2.

The variable phase-shift circuit 13B, which is connected to the power amplifier 12, includes a phase-shift circuit 16 and amplifiers 11a and 11b. The phase-shift circuit 16, which is disposed on the input side of the power amplifier 12, divides a radio frequency signal, which is received by the amplifier circuit 1B through the radio-frequency input terminal 101, into a first radio frequency signal and a second radio frequency signal, and outputs the first radio frequency signal to the amplifier 11a and outputs the second radio frequency signal to the amplifier 11b. The phase-shift circuit 16 sets the phase difference between the first radio frequency signal (phase θ_{I}) and the second radio frequency signal (phase θ_{Q}) to 90°.

The amplifier 11a is an exemplary third amplifier; the amplifier 11b is an exemplary fourth amplifier. The amplifiers 11a and 11b are connected in parallel to each other between the phase-shift circuit 16 and the power amplifier 12.

According to an exemplary aspect, the bias control circuit 17, which is an exemplary control circuit, is configured to control the phase-shift amount of the variable phase-shift circuit 13B. The input end of the bias control circuit 17 is connected to the power-supply-voltage input terminal 103; the output end of the bias control circuit 17 is connected to the amplifiers 11a and 11b of the variable phase-shift circuit 13B. On the basis of the power supply voltage V_{ET} received through the power-supply-voltage input terminal 103, the bias control circuit 17 supplies a bias voltage V_{BI} (first bias voltage) to the amplifier 11a and supplies a bias voltage V_{BQ} (second bias voltage) to the amplifier 11b.

FIG. 9B is a diagram illustrating the phase modulation of the variable phase-shift circuit 13B according to the second modified example of the embodiment. FIG. 9B illustrates, as vectors, the first radio frequency signal (amplitude A_{I} and phase θ_{I}), which has been amplified by the amplifier 11a, and the second radio frequency signal (amplitude A_{Q} and phase θ_{Q}), which has been amplified by the amplifier 11b. The amplitude A_{I} of the first radio frequency signal changes in accordance with the bias voltage V_{BI}; the amplitude Ao of the second radio frequency signal changes in accordance with the bias voltage V_{BQ}. While the phase difference between the first radio frequency signal and the second radio frequency signal is 90°, the phase θ of the combined signal of the first radio frequency signal and the second radio frequency signal changes in accordance with the amplitude ratio between first radio frequency signal and second radio frequency signal.

That is, the variable phase-shift circuit 13B adjusts the amplitudes of the first radio frequency signal and the second radio frequency signal, which are divided by the phase-shift circuit 16, with the bias voltages. This allows the phase-shift amount of the combined radio frequency signal to be changed.

FIG. 10 is a diagram illustrating the circuit configuration of the bias control circuit 17 according to the second modified example of the embodiment. As illustrated in FIG. 10, the bias control circuit 17 includes transistors 171 to 179, a constant current source, multiple resistors, and multiple capacitors.

The transistors 171 and 172 and the transistors 173 and 174 form a current mirror circuit. A collector current, which increases with an increase of the power supply voltage V_{ET}, flows through the transistor 173.

The transistors 175 and 174 and the transistors 176 and 177 form a current mirror circuit. A collector current, which corresponds to the magnitude of a constant current source I_{ref}, flows through the transistor 176.

The base of the transistor 179 is connected to the collector of the transistor 173. Thus, a current, which increases with an increase of the power supply voltage V_{ET}, flows through the emitter of the transistor 179, and the bias voltage V_{BQ}, which increases with an increase of the power supply voltage V_{ET}, is generated.

The base of the transistor 178 is connected to the collector of the transistor 175. Thus, a current, which corresponds to the magnitude of the constant current source I_{ref} (or decreases with an increase of the power supply voltage V_{ET}), flows through the emitter of the transistor 178, and the bias voltage V_{BI}, which corresponds to the magnitude of the constant current source I_{ref} (or decreases with an increase of the power supply voltage V_{ET}), is generated.

That is, according to the circuit illustrated in FIG. 10, with an increase of the power supply voltage V_{ET}, the amplitude A_{I} of the first radio frequency signal, which has been amplified by the amplifier 11a with a decrease of the bias voltage V_{BI}, decreases; the amplitude A_{Q} of the second radio frequency signal, which has been amplified by the amplifier 11b with an increase of the bias voltage V_{BQ}, increases. Thus, with an increase of the power supply voltage V_{ET}, the phase θ of the combined signal of the amplified first radio frequency signal and the amplified second radio frequency signal increases. With a decrease of the power supply voltage V_{ET}, the amplitude A_{I} of the first radio frequency signal, which has been amplified by the amplifier 11a with an increase of the bias voltage V_{BI}, increases; the amplitude Ao of the second radio frequency signal, which has been amplified by the amplifier 11b with a decrease of the bias voltage V_{BQ}, decreases. Thus, with a decrease of the power supply voltage V_{ET}, the phase θ of the combined signal of the amplified first radio frequency signal and the amplified second radio frequency signal decreases. That is, the variable phase-shift circuit 13B and the bias control circuit 17 enable the phase-shift amount of a radio frequency signal to be changed on the basis of the discrete voltage (power supply voltage V_{ET}).

FIG. 10 is an exemplified circuit configuration. According to an exemplary aspect, the bias control circuit 17 may be implemented by using any of diverse circuit implementations and circuit techniques.

The amplifier circuit 1B causes the variable phase-shift circuit 13B and the bias control circuit 17 to change the phase-shift amount of a radio frequency signal in accordance with the power supply voltage V_{ET}, achieving improvement of the characteristics between output signal power (AM) and output signal phase (PM) and a reduction of the nonlinear distortion in the tracking system.

In the amplifier circuit 1B, a driver-stage power amplifier may be connected between the variable phase-shift circuit 13B and the power amplifier 12. In this case, the variable phase-shift circuit 13B is connected to the input end of the driver-stage power amplifier.

In the amplifier circuit 1B, a driver-stage power amplifier may be connected between the variable phase-shift circuit 13B and the radio-frequency input terminal 101. In this case, the variable phase-shift circuit 13B is connected to the input end of the power-stage power amplifier 12.

In the amplifier circuit 1B, the variable phase-shift circuit 13B is not necessarily connected to the input end of the power amplifier 12 (second amplifier) and may be connected to the output end of the power amplifier 12. In this case, a driver-stage power amplifier (first amplifier) may be connected to the input end of the power amplifier 12.

According to this configuration, the variable phase-shift circuit 13B changes the phase-shift amount of a radio frequency signal, which is output from the power amplifier 12, in accordance with the power supply voltage V_{ET} (discrete voltage), achieving improvement of the characteristics between output signal power (AM) and output signal phase (PM). This achieves a reduction of the nonlinear distortion in the tracking system.

### 7 Circuit Configuration of Amplifier Circuit 1C According to Third Modified Example

FIG. 11 is a diagram illustrating the circuit configuration of an amplifier circuit 1C according to a third modified example of the embodiment. As illustrated in FIG. 11, the amplifier circuit 1C includes the power amplifiers 11 and 12, the variable phase-shift circuit 13, the bias circuit 14, a control circuit 15C, the radio-frequency input terminal 101, the radio-frequency output terminal 102, the power-supply-voltage input terminal 103, and control input terminals 106 and 107. The amplifier circuit 1C according to the present modified example is different from the amplifier circuit 1 according to the embodiment in the connection configuration of the control circuit 15C and the variable phase-shift circuit 13. The same configurations of the amplifier circuit 1C according to the present modified example as those of the amplifier circuit 1 according to the embodiment will not be described, and different configurations will be mainly described.

The variable phase-shift circuit 13, which is connected to the power amplifier 11, is configured to change the phase-shift amount of a radio frequency signal, which is to be input to the power amplifier 11, on the basis of a control signal which is output from the control circuit 15C.

The bias circuit 14 is configured to supply bias voltages (bias currents) to the power amplifiers 11 and 12 on the basis of a control signal which is output from the control circuit 15C.

The control circuit 15C controls the variable phase-shift circuit 13 and the bias circuit 14.

Specifically, the control circuit 15C controls the phase-shift amount of the variable phase-shift circuit 13 on the basis of a digital control signal, which is received from the RFIC 3 through the control input terminal 106, and controls the bias voltages of the bias circuit 14 on the basis of the digital control signal which is received from the RFIC 3 through the control input terminal 107.

The control circuit 15C includes a controller 151 and a controller 152.

According to an exemplary aspect, the controller 152 is configured to process a serial data signal (DATA) based on a clock signal (CLK) supplied from the RFIC 3 to generate a control signal S2. The serial data signal can refer to a data signal transmitted one bit by one bit through a single signal line or circuit. Moreover, the control signal S2 is a signal for controlling the bias voltages generated by the bias circuit 14.

According to an exemplary aspect, the controller 151 is configured to process a digital control level (DCL) signal (DCL), which is supplied from the RFIC 3, to generate a control signal S1. The DCL signal is an exemplary parallel data signal. Moreover, the parallel data signal can refer to a data signal transmitted simultaneously and in parallel through multiple signal lines or circuits.

For example, when the digital ET mode is applied to the power amplifiers 11 and 12, the DCL signal is generated by the RFIC 3 on the basis of the envelope signal of a radio frequency signal. Therefore, the control signal S1 is a signal for controlling the phase-shift amount of the variable phase-shift circuit 13 when the digital ET mode is applied to the power amplifiers 11 and 12.

According to this configuration, the phase-shift amount of the variable phase-shift circuit 13 may be changed at high speed on the basis of the envelope signal, enabling the phase-shift amount of the radio frequency signal to be changed in accordance with the power supply voltage V_{ET} (discrete voltage). Thus, the characteristics between output signal power (AM) and output signal phase (PM) may be improved. This achieves a reduction of the nonlinear distortion in the tracking system.

### 8 Technical Effects

As described above, the amplifier circuit 1 according to the present embodiment includes a power amplifier circuit configured to amplify a radio frequency signal by using the power supply voltage V_{ET} (discrete voltage), and the variable phase-shift circuit 13 connected to the power amplifier circuit. The variable phase-shift circuit 13 is configured to change the phase-shift amount of the radio frequency signal on the basis of the power supply voltage V_{ET}.

According to this configuration, the variable phase-shift circuit 13 changes the phase-shift amount of a radio frequency signal in accordance with the power supply voltage V_{ET}, achieving improvement of the characteristics between output signal power (AM) and output signal phase (PM) and a reduction of the nonlinear distortion in the tracking system.

In addition, for example, in the amplifier circuit 1, the power amplifier circuit includes the power amplifier 11 and the power amplifier 12 connected to the output end of the power amplifier 11. The variable phase-shift circuit 13 is connected to the input end of the power amplifier 11.

According to this configuration, the characteristics between output signal power (AM) and output signal phase (PM) are improved. In particular, the efficiency of the amplifier circuit 1 is improved.

In addition, for example, in the amplifier circuit 1A according to the first modified example, the power amplifier circuit includes the power amplifier 11 and the power amplifier 12 connected to the output end of the power amplifier 11. The variable phase-shift circuit 13 is connected to the output end of the power amplifier 11 and the input end of the power amplifier 12.

According to this configuration, the characteristics between output signal power (AM) and output signal phase (PM) is improved. In particular, the noise performance of the amplifier circuit 1A is improved.

In addition, for example, in the amplifier circuit 1, the power amplifier circuit and the variable phase-shift circuit 13 are included in the integrated circuit 81.

According to this configuration, the amplifier circuit 1 can be reduced in size.

In addition, for example, in the amplifier circuit 1C according to the third modified example, the variable phase-shift circuit 13 is configured to change the phase-shift amount in accordance with the parallel data signal.

According to this configuration, the phase-shift amount of the variable phase-shift circuit 13 may be changed at high speed on the basis of the envelope signal, enabling the phase-shift amount of a radio frequency signal to be changed in accordance with the power supply voltage V_{ET} (discrete voltage). This improves the characteristics between output signal power (AM) and output signal phase (PM).

In addition, for example, in the amplifier circuit 1B according to the second modified example, the variable phase-shift circuit 13B includes the phase-shift circuit 16 connected to the input end of the power amplifier circuit, and the amplifiers 11a and 11b connected in parallel to each other between the phase-shift circuit 16 and the power amplifier circuit. The phase-shift circuit 16 outputs the first radio frequency signal to the amplifier 11a, and outputs the second radio frequency signal, which has a phase difference of 90° with respect to the first radio frequency signal, to the amplifier 11b. On the basis of the discrete voltage, the variable phase-shift circuit 13B supplies the first bias voltage to the amplifier 11a and supplies the second bias voltage to the amplifier 11b.

According to this configuration, the variable phase-shift circuit 13B changes the phase-shift amount of a radio frequency signal in accordance with the power supply voltage V_{ET}, achieving improvement of the characteristics between output signal power (AM) and output signal phase (PM) and a reduction of the nonlinear distortion in the tracking system.

In addition, for example, in the amplifier circuit 1, the variable phase-shift circuit 13 is configured to, when the first discrete voltage is supplied to the power amplifier circuit, shift the phase of a radio frequency signal by the first phase-shift amount, and to, when the second discrete voltage larger than the first discrete voltage is supplied to the power amplifier circuit, shift the phase of the radio frequency signal by the second phase-shift amount larger than the first phase-shift amount.

According to this configuration, the variable phase-shift circuit 13 changes the phase-shift amount of a radio frequency signal in accordance with the discrete power supply voltage V_{ET} supplied to the amplifier circuit 1, achieving a reduction of the nonlinear distortion of the radio frequency signal having been amplified by the amplifier circuit 1.

In addition, for example, in the amplifier circuit 1, the variable phase-shift circuit 13 is configured to further increase the phase-shift amount as the discrete voltage increases.

According to this configuration, the variable phase-shift circuit 13 changes the phase-shift amount of a radio frequency signal in accordance with the discrete power supply voltage V_{ET} supplied to the amplifier circuit 1, achieving a reduction of the nonlinear distortion of the radio frequency signal having been amplified by the amplifier circuit 1.

In addition, the amplifier circuit 1B according to the second modified example includes the power-supply-voltage input terminal 103 that receives the power supply voltage V_{ET} (discrete voltage), a power amplifier circuit that is configured to amplify a radio frequency signal by using the power supply voltage V_{ET}, the variable phase-shift circuit 13B that is connected to the power amplifier circuit, and the bias control circuit 17 that controls the phase-shift amount of the variable phase-shift circuit 13B. The input end of the bias control circuit 17 is connected to the power-supply-voltage input terminal 103, and the output end of the bias control circuit 17 is connected to the variable phase-shift circuit 13B.

According to this configuration, the variable phase-shift circuit 13B and the bias control circuit 17 change the phase-shift amount of a radio frequency signal in accordance with the power supply voltage V_{ET}, achieving improvement of the characteristics between output signal power (AM) and output signal phase (PM) and a reduction of the nonlinear distortion in the tracking system.

In addition, for example, in the amplifier circuit 1B, the power amplifier circuit includes a driver-stage power amplifier and the power amplifier 12 connected to the output end of the driver-stage power amplifier. The variable phase-shift circuit 13B is connected to the input end of the driver-stage power amplifier.

According to this configuration, the characteristics between output signal power (AM) and output signal phase (PM) is improved. In particular, the efficiency of the amplifier circuit 1B is improved.

In addition, for example, in the amplifier circuit 1B, the power amplifier circuit includes a driver-stage power amplifier and the power amplifier 12 connected to the output end of the driver-stage power amplifier. The variable phase-shift circuit 13B is connected to the output end of the driver-stage power amplifier and the input end of the power amplifier 12.

According to this configuration, the characteristics between output signal power (AM) and output signal phase (PM) is improved. In particular, the noise performance of the amplifier circuit 1B is improved.

In addition, for example, in the amplifier circuit 1B, the power amplifier circuit includes a driver-stage power amplifier and the power amplifier 12 connected to the output end of the power amplifier. The variable phase-shift circuit 13B is connected to the output end of the power amplifier 12.

According to this configuration, the variable phase-shift circuit 13B changes the phase-shift amount of a radio frequency signal, which is output from the power amplifier 12, in accordance with the power supply voltage V_{ET} (discrete voltage), achieving improvement of the characteristics between output signal power (AM) and output signal phase (PM). This configuration achieves a reduction of the nonlinear distortion in the tracking system.

In addition, for example, in the amplifier circuit 1B, the power amplifier circuit and the variable phase-shift circuit 13B are included in the integrated circuit 81.

According to this configuration, the amplifier circuit 1B can be reduced in size.

In addition, for example, in the amplifier circuit 1B, the variable phase-shift circuit 13B includes the phase-shift circuit 16 connected to the input end of the power amplifier circuit, and the amplifiers 11a and 11b connected in parallel to each other between the phase-shift circuit 16 and the power amplifier circuit. On the basis of the discrete voltage, the bias control circuit 17 supplies the first bias voltage to the amplifier 11a and supplies the second bias voltage to the amplifier 11b.

According to this configuration, the variable phase-shift circuit 13B and the bias control circuit 17 change the phase-shift amount of a radio frequency signal in accordance with the power supply voltage V_{ET}, achieving improvement of the characteristics between output signal power (AM) and output signal phase (PM) and a reduction of the nonlinear distortion the tracking system.

In addition, for example, in the amplifier circuit 1B, the phase-shift circuit 16 outputs the first radio frequency signal to the amplifier 11a, and outputs the second radio frequency signal, which has a phase difference of 90° with respect to the first radio frequency signal, to the amplifier 11b.

According to this configuration, the amplitudes of the first radio frequency signal and the second radio frequency signal are adjusted by using the first bias voltage and the second bias voltage, enabling the phase-shift amount of the combined radio frequency signal of the first radio frequency signal and the second radio frequency signal to be changed.

An amplification method according to the embodiment includes shifting the phase of a first radio frequency signal by a first phase-shift amount on the basis of a first discrete voltage supplied to a power amplifier circuit (S10); amplifying the first radio frequency signal, whose phase has been shifted by the first phase-shift amount, by using the power amplifier circuit which is being supplied with the first discrete voltage (S20); shifting the phase of a second radio frequency signal by a second phase-shift amount, which is different from the first phase-shift amount, on the basis of a second discrete voltage which is different from the first discrete voltage and which is supplied to the power amplifier circuit (S30); and amplifying the second radio frequency signal, whose phase has been shifted by the second phase-shift amount, by using the power amplifier circuit which is being supplied with the second discrete voltage (S40).

According to this configuration, the phase-shift amount of a radio frequency signal is changed in accordance with the power supply voltage V_{ET} (discrete voltage), achieving improvement of the characteristics between output signal power (AM) and output signal phase (PM). This achieves a reduction of the nonlinear distortion in the tracking system.

### Additional Exemplary Embodiments

As described above, the amplifier circuit and the amplification method according to the exemplary aspects of the present disclosure are described on the basis of the embodiment. However, the amplifier circuit and the amplification method described herein are not limited to the embodiment described above. A different embodiment implemented by using a combination of any components in the embodiment, a modified example obtained by making, on the embodiment, various modifications conceived by those skilled in the art without departing from the gist of the exemplary aspects, or various devices including the amplifier circuit are also encompassed in the present disclosure.

For example, in the circuit configuration of various circuits according to the embodiments, a different circuit device, wiring line, and the like may be inserted between paths connecting circuit devices and signal paths disclosed in the drawings.

The exemplary aspects of the present disclosure may be used widely as an amplifier circuit, which is disposed in a multi-band that can be configured as a frontend unit, in communication devices such as a mobile phone.

### REFERENCE SIGNS LIST

1, 1A, 1B, 1C amplifier circuit
2 tracker circuit
3 RFIC
4 BBIC
5 antenna
6 radio frequency circuit
7 communication device
11, 12 power amplifier
11a, 11b amplifier
13, 13B variable phase-shift circuit
14 bias circuit
15, 15C control circuit
16 phase-shift circuit
17 bias control circuit
81, 82 integrated circuit
90 module substrate
90a principal surface
101 radio-frequency input terminal
102 radio-frequency output terminal
103 power-supply-voltage input terminal
104, 105, 106, 107 control input terminal
151, 152 controller
171, 172, 173, 174, 175, 176, 177, 178, 179 transistor
210 amplifier transistor

1. An amplifier circuit comprising:
a power amplifier circuit configured to amplify a radio frequency signal by using a voltage of a plurality of discrete voltage levels; and
a variable phase-shift circuit connected to the power amplifier circuit and configured to change a phase-shift amount of the radio frequency signal based on the voltage of the discrete voltage levels.

2. The amplifier circuit according to claim 1, wherein the power amplifier circuit includes:
a first amplifier having an input end connected to the variable phase-shift circuit, and
a second amplifier connected to an output end of the first amplifier.

3. The amplifier circuit according to claim 1, wherein the power amplifier circuit includes:
a first amplifier, and
a second amplifier connected to an output end of the first amplifier, and
wherein the variable phase-shift circuit is connected to the output end of the first amplifier and an input end of the second amplifier.

4. The amplifier circuit according to claim 1, further comprising a first integrated circuit that includes the power amplifier circuit and the variable phase-shift circuit.

5. The amplifier circuit according to claim 1, wherein the variable phase-shift circuit is configured to change the phase-shift amount in accordance with a parallel data signal.

6. The amplifier circuit according to claim 1, wherein the variable phase-shift circuit includes:
a phase-shift circuit connected to an input end of the power amplifier circuit, and
a third amplifier and a fourth amplifier that are connected in parallel to each other and between the phase-shift circuit and the power amplifier circuit.

7. The amplifier circuit according to claim 6, wherein the phase-shift circuit is configured to output a first radio frequency signal to the third amplifier, and to output, to the fourth amplifier, a second radio frequency signal that has a phase difference of 90° with respect to the first radio frequency signal.

8. The amplifier circuit according to claim 7, wherein the variable phase-shift circuit is configured to supply, based on the voltage of the discrete voltage levels, a first bias voltage to the third amplifier and a second bias voltage to the fourth amplifier.

9. The amplifier circuit according to claim 1, wherein the variable phase-shift circuit is configured to:
shift a phase of the radio frequency signal by a first phase-shift amount when a first discrete voltage is supplied to the power amplifier circuit, and
shift the phase of the radio frequency signal by a second phase-shift amount larger than the first phase-shift amount when a second discrete voltage larger than the first discrete voltage is supplied to the power amplifier circuit.

10. The amplifier circuit according to claim 9, wherein the variable phase-shift circuit is configured to increase the phase-shift amount as the voltage of the discrete voltage levels increases.

11. An amplifier circuit comprising:
a first input terminal configured to receive a voltage of a plurality of discrete voltage levels;
a power amplifier circuit configured to amplify a radio frequency signal by using the voltage of the plurality of discrete voltage levels;
a variable phase-shift circuit connected to the power amplifier circuit; and
a control circuit configured to control a phase-shift amount of the variable phase-shift circuit, the control circuit including an input end connected to the first input terminal and an output end connected to the variable phase-shift circuit.

12. The amplifier circuit according to claim 11, wherein the power amplifier circuit includes:
a first amplifier having an input end connected to the variable phase-shift circuit, and
a second amplifier connected to an output end of the first amplifier.

13. The amplifier circuit according to claim 11, wherein the power amplifier circuit includes:
a first amplifier, and
a second amplifier connected to an output end of the first amplifier, and
wherein the variable phase-shift circuit is connected to the output end of the first amplifier and an input end of the second amplifier.

14. The amplifier circuit according to claim 11, wherein the power amplifier circuit includes:
a first amplifier, and
a second amplifier connected to an output end of the first amplifier, and
wherein the variable phase-shift circuit is connected to an output end of the second amplifier.

15. The amplifier circuit according to claim 11, further comprising a first integrated circuit that includes the power amplifier circuit and the variable phase-shift circuit.

16. The amplifier circuit according to claim 11, wherein the variable phase-shift circuit includes:
a phase-shift circuit connected to an input end of the power amplifier circuit, and
a third amplifier and a fourth amplifier that are connected in parallel to each other and between the phase-shift circuit and the power amplifier circuit.

17. The amplifier circuit according to claim 16 wherein the control circuit is configured to supply, based on the voltage of the discrete voltage levels, a first bias voltage to the third amplifier and a second bias voltage to the fourth amplifier.

18. The amplifier circuit according to claim 17, wherein the phase-shift circuit is configured to output a first radio frequency signal to the third amplifier and a second radio frequency signal to the fourth amplifier that has a phase difference of 90° with respect to the first radio frequency signal.

19. An amplification method comprising:
shifting a phase of a first radio frequency signal by a first phase-shift amount based on a first discrete voltage supplied to a power amplifier circuit;
amplifying, by the power amplifier circuit that is supplied with the first discrete voltage, the first radio frequency signal having a phase shifted by the first phase-shift amount;
shifting a phase of a second radio frequency signal by a second phase-shift amount based on a second discrete voltage, the second phase-shift amount being different from the first phase-shift amount, and the second discrete voltage being different from the first discrete voltage and supplied to the power amplifier circuit; and
amplifying, by the power amplifier circuit supplied with the second discrete voltage, the second radio frequency signal having a phase shifted by the second phase-shift amount.
